(19) United States
(12) Patent Application Publication
(10) Pub. No.: US 2010/0018578 A1
(43) Pub. Date: Jan. 28, 2010

(54) PHOTOACTIVE MATERIALS CONTAINING GROUP IV NANOSTRUCTURES AND OPTOELECTRONIC DEVICES MADE THEREFROM

(76) Inventors: Pingrong Yu, Sunnyvale, CA (US); Dmytro Poplavskyy, San Jose, CA (US); Sanjai Sinha, Santa Clara, CA (US)

Correspondence Address: Foley & Lardner LLP, 150 East Gilman Street, Madison, WI, 53701-1497, US

(21) Appl. No.: 11/756,829

(22) Filed: Jun. 1, 2007

Related U.S. Application Data
(60) Provisional application No. 60/810,326, filed on Jun. 2, 2006.

(51) Int. Cl. H01L 31/04; H01B 1/24

(52) U.S. Cl. 136/261; 252/501.1; 136/263

(57) ABSTRACT

The present invention provides photoactive materials that include inorganic nanostructures comprising a Group IV semiconductor in combination with electron-transporting, conjugated small molecules, carbon nanostructures, or both. The carbon nanostructures or conjugated small molecules may be selected such that the inorganic nanostructures and the carbon nanostructures (and/or the small molecules) exhibit a type II band offset. The photovoltaic materials are well-suited for use as the active layer in photoactive devices, including photovoltaic devices, photoconductors, and photodetectors.

### CROSS-REFERENCE TO RELATED APPLICATIONS

This application claims the benefit of U.S. Provisional Patent Application Ser. No. 60/810,326 filed Jun. 2, 2006, the entire disclosure of which is incorporated by reference.

### FIELD OF THE INVENTION

This invention generally relates to photoactive materials made from Group IV semiconductor nanostructures in combination with electron-transporting, conjugated small molecules or carbon nanostructures, such as fullerenes. The invention also relates to methods for making the photoactive materials and devices incorporating the photoactive materials.

### BACKGROUND

Quantum dots are nanometric scale particles, or “nanoparticles,” that show quantum confinement effects. In the case of semiconductor nanoparticles having spatial dimensions less than the exciton Bohr radius, the quantum confinement effect manifests itself in the form of size-dependent tunable band gaps and, consequently, tunable light absorption and emission properties.

To exploit the tunable properties, semiconductor quantum dots have been incorporated into devices, such as photovoltaic cells and light-emitting diodes, typically in the form of films having suitable electronic and optical coupling with the device and the outside world. For example, U.S. Pat. No. 6,878,871 and U.S. Patent Application Publication Nos. 2005/0126628 and 2004/0095658 describe photovoltaic devices having an active layer that includes inorganic nanostructures, optionally dispersed in a conductive polymer binder, Similarly, U.S. Patent Application Publication No. 2003/0226498 describes semiconductor nanocrystal/conjugated polymer thin films, and U.S. Patent Application Publication No. 2004/0126582 describes materials comprising semiconductor particles embedded in an inorganic or organic matrix. Notably, these references focus on the use of Group II-VI or Group III-V nanostructures in photovoltaic devices, rather than on the use of Group IV nanostructures. This is significant for at least two reasons. First, Group II-VI and Group II-V nanostructures have very different reactivities and chemistries than Group IV nanostructures, and, therefore, many processing steps (e.g., surface-functionalization, solubilization, etc.) that work for Group II-VI and Group III-V nanostructures are inoperable for Group IV nanostructures. Second, Group II-VI and Group III-V nanostructures are more suited for electron conduction, while Group IV nanostructures, such as silicon (Si) and germanium (Ge), can also be employed as hole conductors. Therefore, the considerations for selecting appropriate materials for a photoactive layer based on Group IV nanostructures are very different from those for photoactive layers based on Group II-VI or Group III-V nanostructures.

Carbon nanostructures, including fullerenes, have also been used in photovoltaic devices, including organic photovoltaic devices. For example, U.S. Pat. No. 5,171,373 describes solar cells that incorporate fullerenes into the active layer. Similarly, U.S. Pat. Nos. 5,454,880 and 6,812,399 describe photoactive devices that include conjugated polymers and fullerenes. However, none of these references describes a photovoltaic device including both fullerenes and Group IV nanostructures.

### SUMMARY

The present invention provides photoactive materials that include inorganic nanostructures comprising a Group IV semiconductor in combination with electron-transporting, conjugated small molecules, carbon nanostructures, or both. The carbon nanostructures or conjugated small molecules may be selected such that the inorganic nanostructures and the carbon nanostructures (and/or the small molecules) exhibit a type II band offset. The photovoltaic materials are well-suited for use as the active layer in photoactive devices, including photovoltaic devices, photoconductors, and photodetectors. However, the photoactive materials may also be used in light-emitting devices, such as light-emitting diodes.

The inorganic nanostructures may be any Group IV semiconductor-containing nanostructure including, but limited to, Group IV nanocrystals and nanowires. The nanostructures may be composed of Group IV semiconductor alloys (e.g., alloys of Si and Ge (i.e., “SiGe alloys”)); or they may be core/shell nanostructures wherein the core, the shell, or the core and the shell include, or are entirely composed of, a Group IV element, Suitable examples of core/shell nanoparticles include nanoparticles having an Si core and a Ge shell (“SiGe core/shell nanoparticles”) or nanoparticles having a Ge core and an Si shell (“GeSi core/shell nanoparticles”). The nanostructures may also be capped with organic ligands which passivate the surface of the nanoparticles and/or facilitate their incorporation into a matrix. The ligands may be present as a result of the process used to make the nanostructures, or they may be attached to the nanostructures in a separate processing step, after the nanostructures have been formed.

The inorganic nanostructures are combined with an electron-transporting moiety in the photoactive materials. In some aspects of the invention, the electron-transporting moieties are conjugated small molecules, such as tetracyanoquinodimethane (TCNQ), perylene and its derivatives, (4,7-diphenyl-1,10-phenanthroline) (BPhen), tris(8-hydroxyquinolinato)aluminum (Alq₃), or diphenyl-p-t-butylphenyl-1,3,4-oxadiazole (PBD). In other aspects of the invention, the electron-transporting moieties are carbon nanostructures, such as fullerenes or carbon nanotubes.

The inorganic nanostructures and the small molecules and/or carbon nanostructures may be contained in a single layer, such that they provide a bulk heterojunction. Alternatively, the inorganic nanostructures and the small molecules and/or carbon nanostructures may be contained in separate sublayers of the photoactive material. Within the photoactive materials, the inorganic nanostructures, carbon nanostructures, and/or conjugated small molecules may be dispersed in a matrix, such as a polymer matrix. However, a polymer matrix may be absent and the nanostructures or small molecules may themselves form a matrix or mixture. When a polymer matrix is present, the polymer may be a non-conducting or an electrically conducting polymer. Preferred polymers include electrically conducting, conjugated polymers.

Photoactive devices made from the photoactive materials generally include the photoactive material in electrical communication with a first electrode and a second electrode. Other layers commonly employed in photoactive devices (e.g., barrier layers, blocking layers, recombination layers, insulating layers, protective casings, etc.) may also be incorporated into the devices.

Further objects, features and advantages of the invention will be apparent from the following detailed description when taken in conjunction with the accompanying drawings.

### BRIEF DESCRIPTION OF THE DRAWINGS

FIG. 1 shows a schematic cross-sectional view of a photovoltaic device in accordance with the present invention.

FIG. 2 shows the I-V curves for a photovoltaic device having an active layer comprising a photoactive material that includes a blend of Ge nanocrystals and PCBM fullerenes (red curves). The I-V curves for a photovoltaic device having an active layer of Ge nanocrystals, without a polymer matrix or fullerenes, is also shown (black curves).

### DETAILED DESCRIPTION

The present invention provides photoactive materials that include inorganic nanostructures comprising a Group IV semiconductor in combination with electron-transporting conjugated small molecules, carbon nanostructures, or both. The carbon nanostructures or conjugated small molecules may be selected such that the inorganic nanostructures and the carbon nanostructures (and/or the small molecules) exhibit a type II band offset, where two materials have a “type II band offset” if the conduction band or valence band, but not both, of one material is within the bandgap of the other material.

The photoactive materials are well-suited for use as the active layer in photoactive devices (i.e., devices that convert electromagnetic radiation into electrical energy), including photovoltaic devices, photoconductors and photodetectors. A typical photovoltaic cell incorporating the present photoactive materials operates as follows. When the inorganic nanostructures in the active layer are exposed to light, the Group IV semiconductors absorb light, creating an exciton (i.e., an electron/hole pair) within the nanostructure. The electron of the exciton is then conducted away from the hole and the electrons are conducted out of the active layer through electrodes, resulting in the creation of an electric current. This process is facilitated by the organic small molecules and/or carbon nanostructures which help to transport the electrons away from the nanostructures. The process may be further facilitated by dispersing the inorganic nanostructures in a conductive polymer capable of transporting the electrons and/or holes away from the nanostructures.

As used herein, the term nanostructure generally refers to structures having a diameter in at least one dimension (e.g., length, width or height) of no more than about 500 nm, desirably no more than about 200 nm, more desirably no more than about 100 nm, and still more desirably no more than about 50 nm, or even 10 nm. For some nanostructures, at least two, and in some cases all three, dimensions of the nanostructure will fall into the above-referenced size limitations. The nanostructures may be generally spherical, as in the case of semiconductor quantum dots and C₆₀ fullerenes, or elongated, as in the case of semiconductor nanowires or carbon nanotubes. In some instances the elongated nanostructures will have an aspect ratio (i.e., the ratio of the length of the nanostructure to the width of the nanostructure) of at least 2, and desirably at least 11. In other cases, the nanostructures may take on more complex geometries, including branched geometries or shapes, such as cubic, pyramidal, double square pyramidal, or cubeoctahedral. The nanostructures within a given population of nanostructures may have a variety of shapes, and a given population of nanostructures may include nanostructures of different sizes.

The inorganic semiconductor nanostructures in the present photoactive materials include a Group IV semiconductor. Preferred inorganic nanostructures include silicon and germanium nanocrystals having an average diameter of about 100 nm or less. This includes nanocrystals having an average diameter of about 50 nm or less. For example, the population of silicon and or germanium nanocrystals in a photoactive material may have an average diameter of about 3 nm to about 20 nm. The inorganic nanostructures may exhibit a number of unique electronic, magnetic, catalytic, physical, optoelectronic and optical properties due to quantum confinement effects. These quantum confinement effects may vary as the size of the nanostructure is varied.

Group IV nanostructures include, but are not limited to, Si nanocrystals and nanowires, Ge nanocrystals and nanowires, Sn nanocrystals and nanowires, SiGe alloy nanocrystals and nanowires, and nanocrystals and nanowires comprising alloys of tin and Si and/or Ge. The nanostructures may be nanoparticles that include a core and an inorganic shell. Such nanoparticles shall be referred to as “core/shell nanoparticles.” The core/shell nanoparticles of the present invention include a Group IV semiconductor in their shell, in their core, or in both their core and their shell. For example, the core/shell nanoparticles may include an Si core and a Ge shell, or a Ge shell and an Si core.

In some embodiments, the inorganic nanostructure may be hydrogen-terminated or capped by organic molecules which are bound to, or otherwise associated with, the surface of the nanostructures. These organic molecules may passivate the nanostructures and/or facilitate the incorporation of the nanostructures into a polymer matrix. Examples of suitable passivating organic ligands include, but are not limited to, perfluoroalkenes, perfluoroalkene-sulfonic acids, alkylenes, polyesters, nonionic surfactants, and alcohols. Specific examples of capping agents for inorganic nanoparticles are described in U.S. Pat. No. 6,846,565, the entire disclosure of which is incorporated herein by reference. The capping ligands may be associated with the surface of the nanostructures during the formation of the nanostructures, or they may be associated with the nanostructures in a separate processing step, after nanostructure formation.

The inorganic nanostructures (e.g., nanocrystals) in the material may have a polydisperse or a substantially monodisperse size distribution. As used herein, the term “substantially monodisperse” refers to a plurality of nanostructures which deviate by less than 20% root-mean-square (rms) in diameter, more preferably less than 10% rms, and most preferably less than 5% rms, where the diameter of a nanostructure refers to the largest cross-sectional diameter of the nanostructure. The term polydisperse refers to a plurality of nanostructures having a size distribution that is broader than monodisperse. For example, a plurality of nanostructures which deviate by at least 25%, 30%, or 35% rms in diameter would be a polydisperse collection of nanostructures. One advantage of using a population of inorganic nanostructures having a polydisperse size distribution is that different nanostructures in the population will be capable of absorbing light of different wavelengths. This may be particularly desirable in applications, such as photovoltaic cells, wherein absorption efficiency is important.

In addition to, or as an alternative to, tuning the absorption characteristics of the photoactive material by using nanostructures of different sizes, the absorption characteristics of the photoactive material may be tuned by using inorganic nanostructures having different chemical compositions. For example, the active layer can include a blend of Si and Ge nanocrystals.

The nanostructures are desirably not grown from any device layer in a photoactive devices and, as such, are easily distinguishable from, e.g., amorphous silicon structures that are grown from, and therefore in direct contact with, a substrate that is incorporated into a photoactive device. In preferred embodiments, at least some of the inorganic nanostructures are not in direct contact with layers, other than the active layer, of a photoactive device.

Suitable methods for forming inorganic nanostructures comprising Group IV semiconductors may be found in U.S. Pat. Nos. 6,268,041 and 6,846,565, and U.S. Patent Application Publication No. 2006/0051505, the entire disclosures of which are incorporated herein by reference.

### Carbon Nanostructures:

The carbon nanostructures in the photoactive materials facilitate electron transport and desirably exhibit a type II band offset relative to the inorganic nanostructures. Like the inorganic nanostructures, the carbon nanostructures may be substantially spherical or elongated. Suitable carbon nanostructures include fullerenes, where a fullerene is a cage-like, hollow, carbon molecule composed of hexagonal and pentagonal groups of carbon atoms. Specific examples of suitable fullerenes include fullerenes having 60 carbon atoms (“C₆₀”), fullerenes having 70 carbon atoms (“C₇₀”), and the like. Elongated carbon nanostructures include carbon nanotubes, nanofibers, and nanowhiskers.

The carbon nanostructures may be substituted fullerenes, fullerene derivatives, or modified fullerenes. For example, the fullerenes may have substituents on one or more carbon atoms or may have one or more carbon atoms in the skeleton replaced by another atom. [6,6]-phenyl C61-butyric acid methyl ester (PCBM), a soluble derivative of C₆₀, is a specific example of a suitable fullerene derivative.

### Organic Conjugated Small Molecules:

The organic conjugated small molecules may be any conjugated small molecules that provide electron transport in the photoactive materials. As used herein, the term “small molecule” includes molecules, including oligomers, having a molecular weight of no more than about 1000 and desirably no more than about 500. Examples of suitable organic conjugated small molecules include TCNQ, perylene and its derivatives, 4,7-diphenyl-1,10-phenanthroline (BPhen), tris(8-hydroxyquinolinato)aluminum (Alq₃), or diphenyl-p-t-butylphenyl-1,3,4-oxadiazole (PBD), and other organic acceptors that can take on an extra electron into the π-electron system.

### The Photoactive Material:

Within the photoactive material, the inorganic nanostructures and the carbon nanostructures and/or small molecules may be in the form of a neat mixture; that is, a mixture without any matrix or binder, other than any matrix formed by the nanostructures and/or the small molecules themselves. Alternatively, the inorganic nanostructures and the carbon nanostructures or organic small molecules may be contained within different sublayers of the photoactive material. These sublayers may be in direct contact, such that a heterojunction is formed between the sublayers. In some embodiments, the photoactive materials include three or more sublayers, which may provide a series of (i.e., two or more) heterojunctions. Each sublayer in a multilayered photoactive material may contain a different population (in terms of size distribution and/or chemical composition) of nanostructures and/or organic small molecules. In some embodiments, the compositions and/or size distributions of the nanostructures in different sublayers may be different, such that different sublayers have different light-absorbing characteristics. For example, the sublayers may be arranged with an ordered distribution, such that the inorganic semiconductor nanostructures having the highest bandgaps are near one surface of a multilayered photoactive material and the inorganic nanostructures having the lowest bandgaps are near the opposing surface of a multilayered photoactive material.

Optionally, the inorganic nanostructures, the carbon nanostructures, and/or the organic small molecules (whether in a single layer or in separate sublayers) may be dispersed in a polymer matrix or binder. The polymer is desirably, but not necessarily, an electrically conductive polymer. Many suitable electrically conductive polymers are known and commercially available. These include, but are not limited to, conjugated polymers such as polythiophenes, poly(phenyl vinylene) (PPV) and its derivatives, polyaniline, and polyfluorene and its derivatives. Other suitable conjugated polymers that may be used as a matrix in the photoactive materials are described in U.S. Patent Application Publication No. 2003/0226498, the entire disclosure of which is incorporated herein by reference.

Within the photoactive material, elongated inorganic nanostructures, elongated carbon nanostructures, or both may be oriented randomly, or may be oriented non-randomly with a primary alignment direction perpendicular to the surface of the material. A population of elongated nanostructures is “non-randomly oriented with a primary alignment direction perpendicular to the surface of the material” if significantly more (e.g., ≧5% or ≧10% more) of the elongated nanostructures are aligned in a perpendicular orientation relative to a completely random distribution of nanostructures. In some embodiments, both the inorganic and carbon nanostructures will be non-randomly oriented within the photoactive material.

Generally, the photoactive material has an inorganic nanostructure content that is sufficiently high to allow the material to conduct the electrons and holes generated when the material is exposed to light. The desired nanostructure loading will depend on the sensitivity and/or efficiency requirements for the particular application and on the composition of the nanostructures in the photoactive material. For example, nanostructures made from lower bandgap semiconductors, such as Ge, typically require lower nanostructure loadings. In some embodiments a volume loading of inorganic nanostructures of at least about 1% may be sufficient. However, for some applications, higher inorganic nanostructure loadings may be desirable (e.g., about 1 to about 50%, or even up to 80%). Thus, in some embodiments the photoactive material may have an inorganic nanostructure loading of at least about 10% by volume. This includes embodiment where the photoactive material has a nanostructure loading of at least about 20%, at least about 30%, at least about 35%, at least about 40%, at least about 45%, at least about 50%, at least 60%, at least 70%, and at least 80% by volume. For example, in some embodiments the photoactive material will have an inorganic nanostructure loading of about 35 to about 50% by volume.

When the photoactive materials include carbon nanostructures, the ratio of inorganic nanostructures to carbon nanostructures in the photoactive materials may vary over a fairly broad range. For example, the weight ratio of inorganic nanoparticles to carbon nanoparticles may range from about 10:1 to 1:10. This includes embodiments where the ratio ranges from about 5:1 to 1:5; from about 2:1 to 1:2; and from about 1.5:1 to 1:1.5.

### Photoactive Devices:

The photoactive materials may be used in a variety of devices which convert electromagnetic radiation into an electric signal. Such devices include photovoltaic cells, photoconverters, and photodetectors. Generally, these devices will include the photoactive material electrically coupled to two or more electrodes. Each layer in the device may be quite thin, e.g., having a thickness of no more than about 500 nm, no more than about 300 nm, or even no more than about 100 nm. When the photoactive material is used in a photovoltaic cell, the device may further include a power-consuming device (e.g., a lamp, a computer, etc.) which is in electrical communication with, and powered by, one or more photovoltaic cells. When the photoactive material is used in a photoconductor or photodetector, the device further includes a current detector coupled to the photoactive material.

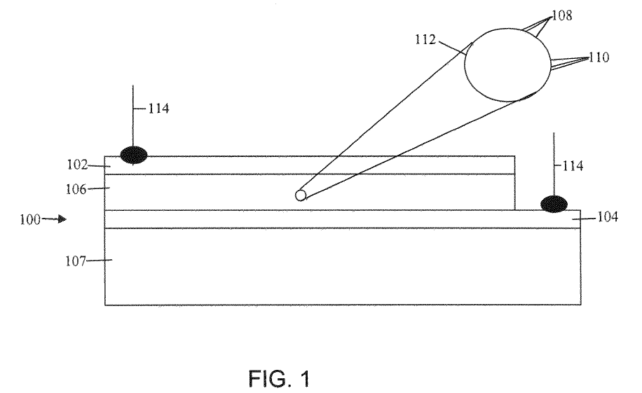

FIG. 1 shows a schematic diagram of a cross-sectional view of one example of a simple photovoltaic device 100 in accordance with the present invention. The device of FIG. 1 includes a first electrode 102, a second electrode 104, and a photoactive material 106 disposed between, and in direct contact with, the first and second electrodes. Although the photoactive material is in direct contact with the electrodes in the depicted embodiment, it is necessary only that the photoactive material and the electrodes be in electrical communication; that is, connected to allow for electrical current flow. Thus, direct contact between the electrodes and the active layer is not necessary, and other layers, such as electron-injecting, hole-injecting, blocking, or recombination layers, may be disposed between the electrodes and the photoactive material. As shown in the figure, one electrode may be supported by an underlying substrate 107. As shown in the inset of FIG. 1, the photoactive material 106 is a single-layer material containing inorganic semiconductor nanocrystals 108 and fullerenes 110. In this illustrative embodiment, the nanocrystals and fullerenes are dispersed in a polymer matrix 112. At least one of the two electrodes and, optionally, the substrate, is desirably transparent, such that it allows light to reach the photoactive material. In addition, the electrodes and substrate are desirably thin and flexible, such that the entire device structure provides a thin film photovoltaic cell. Indium tin oxide (ITO) on a flexible, transparent polymer substrate, is an example of a transparent, flexible electrode material. The electrodes are in electrical communication (e.g., via wires 114) with some type of load, such as an external circuit or a power-consuming device (not shown).

### Method of Making a Photovoltaic Device:

A photovoltaic device may be fabricated from the photoactive materials as follows. A substrate with a bottom electrode (e.g., ITO on a polymer film) is cleaned and a thin layer (e.g., about 30-100 nm) of PEDOT:PSS is spin-coated onto the electrode. An active layer comprising a blend of Ge nanocrystals and PCBM is formed over the PEDOT:PSS by spin-coating a solution of Ge nanocrystals and PCBM (with a weight ratio of about 1:1) in chloroform. Finally, 200 nm of aluminum top electrode is deposited over the active layer.

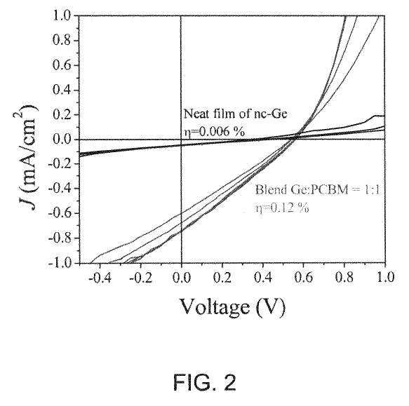

FIG. 2 shows the I-V curves for a photovoltaic device having an active layer comprising a photoactive material that includes a blend of Ge nanocrystals and PCBM fullerenes (red curves). The I-V curves for a photovoltaic device having an active layer of Ge nanocrystals, without a polymer matrix or binder or fullerenes, is also shown (black curves).

For the purposes of this disclosure and unless otherwise specified, “a” or “an” means “one or more.” All patents, applications, references and publications cited herein are incorporated by reference in their entirety to the same extent as if they were individually incorporated by reference.

As will be understood by one skilled in the art, for any and all purposes, particularly in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art, all language such as “up to,” “at least,” “greater than,” “less than,” and the like includes the number recited and refers to ranges which can be subsequently broken down into subranges as discussed above. Finally, as will be understood by one skilled in the art, a range includes each individual member.

While the principles of this invention have been described in connection with specific embodiments, it should be understood clearly that these descriptions are made only by way of example and are not intended to limit the scope of the invention.

What is claimed is:

1. A photoactive material comprising a plurality of inorganic nanostructures comprising a Group IV semiconductor and a plurality of carbon nanostructures.

2. The material of claim 1, wherein the inorganic nanostructures and the carbon nanostructures exhibit a type II band offset.

3. The material of claim 1, wherein the inorganic nanostructures are selected from the group consisting of silicon nanostructures, germanium nanostructures, tin nanostructures, SiGe core/shell nanostructures, GeSi core/shell nanostructures, SiGe alloy nanostructures, nanostructures comprising alloys of Sn with Si and/or Ge, or a mixture thereof.

4. The material of claim 1, wherein the inorganic nanostructures are capped with organic ligands.

5. The material of claim 1, wherein at least some of the inorganic nanostructures are elongated and the elongated inorganic nanostructures are randomly oriented in the composite material.

6. The material of claim 1, wherein at least some of the inorganic nanostructures are elongated and the elongated inorganic nanostructures are non-randomly oriented in the composite material with a primary alignment direction perpendicular to the surface of the material.

7. The material of claim 1, wherein the carbon nanostructures comprise fullerenes or carbon nanotubes.

8. The material of claim 6, wherein at least some of the carbon nanostructures are elongated and the elongated carbon nanostructures are non-randomly oriented in the material with a primary alignment direction perpendicular to the surface of the material.

9. The material of claim 1, wherein the inorganic nanostructures and the carbon nanostructures are contained in a single layer.

10. The material of claim 1, wherein the material comprises at least two sublayers and the inorganic nanostructures and the carbon nanostructures are contained in separate sublayers.

11. The material of claim 1, further comprising electron-transporting, conjugated organic small molecules.

12. The material of claim 9, wherein the inorganic nanostructures and the carbon nanostructures are dispersed in a matrix material.

13. The material of claim 10, wherein the inorganic nanostructures, the carbon nanostructures, or both are dispersed in a matrix material.

14. The material of claim 12, wherein the matrix material comprises a conductive polymer.

15. The material of claim 1, wherein the weight ratio of inorganic nanostructures to carbon nanostructures in the material is from about 10:1 to 1:10.

16. An optoelectronic device comprising:
(a) a first electrode;
(b) a second electrode;
(c) a photoactive layer comprising the material of claim 1 in electrical communication with the first and second electrodes.

17. A method of converting electromagnetic radiation to electric energy comprising exposing the device of claim 16 to light comprising wavelengths sufficient to generate electrons and holes in the photoactive layer.

18. A photoactive material comprising a plurality of inorganic nanostructures comprising a Group IV semiconductor and conjugated organic small molecules.

19. The material of claim 18, wherein the inorganic nanostructures and the small molecules exhibit a type II band offset.

20. The material of claim 18, wherein the inorganic nanostructures are selected from the group consisting of silicon nanostructures, germanium nanostructures, tin nanostructures, SiGe core/shell nanostructures, GeSi core/shell nanostructures, SiGe alloy nanostructures, nanostructures comprising alloys of Sn with Si and/or Ge, or a mixture thereof.

21. The material of claim 18, wherein at least some of the inorganic nanostructures are elongated and the elongated inorganic nanostructures are randomly oriented in the composite material.

22. The material of claim 18, wherein at least some of the inorganic nanostructures are elongated and the elongated inorganic nanostructures are non-randomly oriented in the composite material with a primary alignment direction perpendicular to the surface of the material.

23. The material of claim 18, wherein the small molecules are selected from the group consisting of tetracyanoquinodimethane, perylene and its derivatives, (4,7-diphenyl-1,10-phenanthroline), tris(8-hydroxyquinolinato)aluminum, or diphenyl-p-t-butylphenyl-1,3,4-oxadiazole.

24. The material of claim 18, wherein the inorganic nanostructures and the small molecules are contained in a single layer.

25. The material of claim 18, wherein the material comprises at least two sublayers and the inorganic nanostructures and the small molecules are contained in separate sublayers.

26. The material of claim 24, wherein the inorganic nanostructures and the small molecules are dispersed in a matrix material.

27. The material of claim 25, wherein the inorganic nanostructures, the small molecules, or both are dispersed in a matrix material.

28. The material of claim 26, wherein the matrix material comprises a conductive polymer.

29. An optoelectronic device comprising:
(a) a first electrode;
(b) a second electrode;
(c) a photoactive layer comprising the material of claim 18 in electrical communication with the first and second electrodes.

30. A method of converting electromagnetic radiation to electric energy comprising exposing the device of claim 29 to light-comprising wavelengths sufficient to generate electrons and holes in the photoactive layer.
